(19) United States
(12) Patent Application Publication
(10) Pub. No.: US 2026/0096264 A1
(43) Pub. Date: Apr. 2, 2026

(54) Display Device

(71) Applicant: LG Display Co., Ltd., Seoul (KR)

(72) Inventor: Dong Geun Bae, Paju-si, Gyeonggi-do (KR)

(21) Appl. No.: 18/893,674

(22) Filed: Sep. 23, 2024

(30) Foreign Application Priority Data
Nov. 20, 2023 (KR) 10-2023-0160404

(51) Int. Cl. H10H 29/49; H10H 20/80; H10H 20/831; H10H 29/01; H10H 29/37; H10H 29/855

(52) U.S. Cl. CPC H10H 29/49; H10H 20/831; H10H 20/882; H10H 29/012; H10H 29/37; H10H 29/8552

(57) ABSTRACT

A display device is disclosed which includes: a plurality of first electrodes and a contact electrode disposed on a substrate; a first bank and a second bank disposed on the substrate; a first light-emitting element disposed on the first bank; a second light-emitting element disposed on the second bank; a first optical layer and a first component disposed between the first light-emitting element and the second light-emitting element; and a second electrode disposed on the first light-emitting element and the second light-emitting element. The second electrode extends outwardly of the first optical layer disposed between the first light-emitting element and the second light-emitting element and is electrically connected to the contact electrode.

### CROSS-REFERENCE TO RELATED APPLICATION

This application claims priority to and the benefit of Republic of Korea Patent Application No. 10-2023-0160404, filed on Nov. 20, 2023, which is hereby incorporated by reference in its entirety.

### BACKGROUND

### Field

The present disclosure relates to a display device, and more particularly to a display device including a light-emitting diode.

### Description of Related Art

An electroluminescent display device is used to display an image using spontaneous light-emitting elements, and may be implemented in thin and various forms because it does not require a separate light source, such as a backlight unit.

The electroluminescent display device includes an organic light-emitting display device in which an organic light-emitting diode (OLED) (hereinafter referred to as an “OLED”) is arranged, and an inorganic light-emitting display device (hereinafter referred to as an “LED display device”) in which an inorganic light-emitting diode (LED) (hereinafter referred to as an “LED”) is arranged.

As an example of an inorganic light-emitting display device, micro-LED display devices with micro-LEDs arranged in pixels are emerging as the next generation of display devices. The micro-LEDs may be inorganic light-emitting diodes having a size of 100 [symbol] or less. The micro-LEDs may be fabricated by a separate semiconductor process, and they may be transferred to pixel locations on a substrate for a display panel of the display device and arranged in respective sub-pixel for each color.

### SUMMARY

The LED in the light-emitting diode display device is a point light source, and therefore it may emit light in any direction. When the light-emitting diode display device is implemented as a unidirectional display device, light emitted in any direction other than the display direction will be extinguished, resulting in low light efficiency.

The present disclosure aims to provide a display device with improved light efficiency to address the above problems. However, the problems of the present disclosure are not limited to those mentioned above, and other technical problems may be inferred from the following embodiments.

A display device according to one embodiment of the present disclosure includes a plurality of first electrodes and a contact electrode disposed on a substrate; a first bank and a second bank disposed on the substrate; a first light-emitting element disposed on the first bank; a second light-emitting element disposed on the second bank; a first optical layer and a first component disposed between the first light-emitting element and the second light-emitting element; and a second electrode disposed on the first light-emitting element and the second light-emitting element, wherein the second electrode extends outwardly of the first optical layer disposed between the first light-emitting element and the second light-emitting element and is electrically connected to the contact electrode.

Specific details of other embodiments are set forth in the detailed description and drawings.

The display device according to the present disclosure may have increased light efficiency by disposing a highly reflective metal layer between a plurality of light-emitting elements. In addition, the power consumption of the display device may decrease as the light efficiency increases.

The effects of the present disclosure are not limited to the above-mentioned effects, and other effects that are not mentioned will be apparently understood by those skilled in the art from the following description and the appended claims.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a diagram illustrating a display device according to one embodiment of the present disclosure;

FIG. 2 is an enlarged view of an area ‘A’ in FIG. 1 according to one embodiment of the present disclosure;

FIG. 3 is a diagram illustrating a partial area of a pixel of the display device according to one embodiment of the present disclosure;

FIG. 4 is a cross-sectional view taken along line I-I′ in FIG. 3 according to one embodiment of the present disclosure;

FIG. 5 is a cross-sectional view taken along line II-II′ in FIG. 3 according to one embodiment of the present disclosure;

FIG. 6 is an enlarged view of an area ‘B’ in FIG. 5 according to one embodiment of the present disclosure;

FIGS. 7A to 7G are diagrams illustrating a method of manufacturing the display device according to one embodiment of the present disclosure;

FIG. 8 is a cross-sectional view taken along line II-II′ in FIG. 3 according to another embodiment; and

FIG. 9 is a cross-sectional view taken along line II-II′ in FIG. 3 according to another embodiment.

### DETAILED DESCRIPTION

The advantages and features of the present disclosure, and methods of achieving them will become apparent upon reference to the embodiments described in detail below in conjunction with the accompanying drawings. However, the present disclosure is not limited to the following embodiments, but may be implemented in various different forms; rather, the present embodiments are provided to make the disclosure of the present disclosure complete and to enable those skilled in the art to fully understand the scope of the present disclosure, and the present disclosure is defined only within the scope of the appended claims.

The shapes, sizes, proportions, angles, numbers, and the like of elements shown in the drawings to illustrate embodiments of the present disclosure are merely illustrative and are not intended to be limiting. Further, in describing the present disclosure, detailed descriptions of well-known technologies may be omitted so as not to obscure the essence of the present disclosure.

The terms such as “comprising,” “having,” and “including” used herein are generally intended to allow for the addition of other components unless the terms are used with the term “only.” References to components of a singular noun include the plural of that noun, unless specifically stated otherwise.

In interpreting components, they are construed to include a margin of error, even if it is not explicitly stated.

When describing the positional relationship, for example, if the positional relationship of the two parts is described as “on,” “above,” “below,” and “next to,” one or more other parts may be located between the two parts unless “immediately”or “directly”is used.

When an element or layer is referred to as being on another element or layer, this includes any intervening layer or other element directly on top of or in between the other element.

In addition, first, second, etc., are used to describe various components, but these components are not limited by these terms. These terms are used only to distinguish one component from another. Therefore, the first component referred to below may be a second component within the technical spirit of the present disclosure.

Identical reference numerals may designate identical components throughout the description.

The sizes and thicknesses of each configuration shown in the drawings are shown for illustrative purposes only and are not necessarily limited to the sizes and thicknesses of the configurations shown herein.

Each of the features of various embodiments described herein may be coupled or combined with one another in whole or in part, and may be technologically interlocked and operated in various ways, and each of the embodiments may be carried out independently or in conjunction with one another.

Hereinafter, various embodiments of the present disclosure will be described in detail with reference to the accompanying drawings.

A display device according to one embodiment of the present disclosure includes a display panel having a screen or a display area on which an image is displayed, and a pixel driving circuit for driving pixels on the display panel. The display area includes a pixel area in which the pixels are arranged. The pixel area includes a plurality of light-emitting areas. A light-emitting element is disposed in each of the light-emitting areas. The pixel driving circuit may be embedded in the display panel.

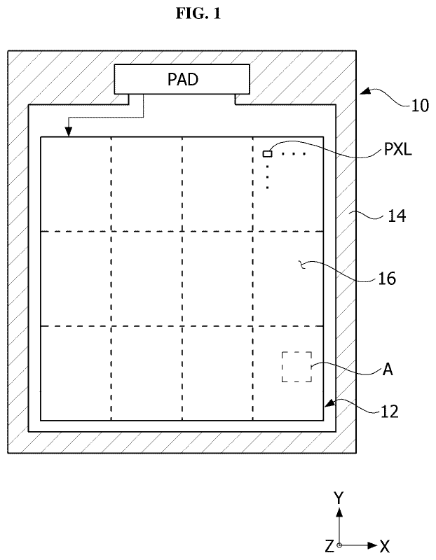

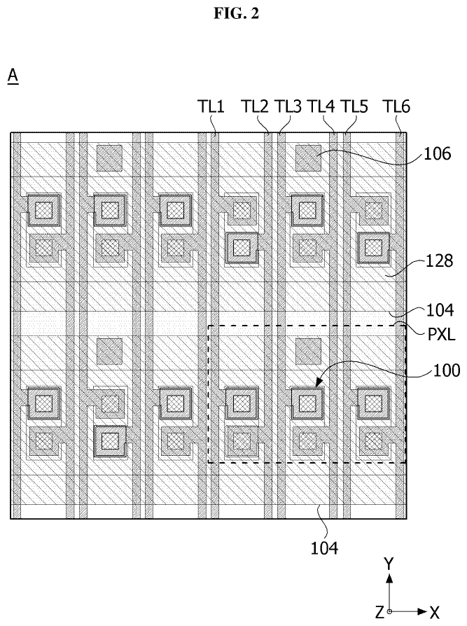

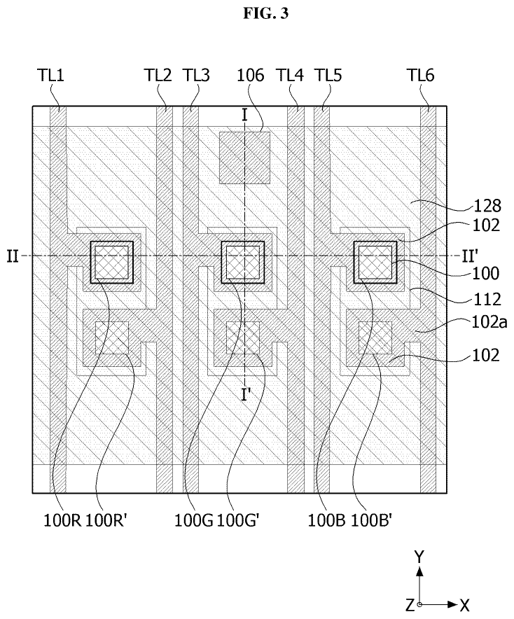

FIG. 1 is a diagram illustrating a display device according to one embodiment of the present disclosure; FIG. 2 is an enlarged view of an area ‘A’ in FIG. 1 according to one embodiment of the present disclosure. FIG. 3 is a diagram illustrating a partial area of a pixel of the display device according to one embodiment of the present disclosure.

Referring to FIGS. 1 and 2, a display device 10 according to an embodiment of the present disclosure includes a display panel on which an input image is visually reproduced. The display panel may include a display area 12 in which the image is displayed and a non-display area 14 in which no image is displayed. In the non-display area 14, various wires and driving circuits may be mounted and a pad portion PAD may be disposed to which integrated circuits, printed circuits, and the like are connected.

A plurality of light-emitting elements 100 disposed in the display area 12 to form the pixels PXL may be micro-sized inorganic light-emitting elements. The inorganic light-emitting elements may be grown on a silicon wafer and then attached to the display panel through a transfer process.

The transfer process of the light-emitting elements 100 may be performed for each pre-divided region. Although FIG. 1 illustrates that the display area 12 is divided into twelve transfer regions 16, the size of the transfer region or the number of divisions of the transfer regions is not limited thereto. The transfer process may be sequentially or simultaneously performed in a first transfer region 16 to a twelfth transfer region 16. A blue light-emitting element 100, a green light-emitting element 100, and a red light-emitting element 100 may be sequentially transferred to the transfer region 16.

In the non-display area 14, a data driving circuit or a gate driving circuit may be disposed and wires for supplying a control signal for controlling the driving circuits may be disposed. Here, the control signal may include various timing signals including a clock signal, an input data enable signal, and synchronization signals, and may be received through the pad portion PAD.

The pixels PXL may be driven by the pixel driving circuit. The pixel driving circuit may receive a driving voltage, an image signal (digital signal), a synchronization signal synchronized with the image signal, and the like and output an anode voltage and a cathode voltage of the light-emitting element 100 to drive the plurality of pixels. The driving voltage may be a high potential voltage EVDD. The cathode voltage may be a low potential voltage EVSS commonly applied to the pixels. The anode voltage may be a voltage corresponding to a pixel data value of the image signal. The pixel driving circuit may be disposed in the non-display area 14, or may be disposed below the display area 12.

Each of the pixels PXL may include a plurality of sub-pixels having different colors. For example, the plurality of sub-pixels may include a red sub-pixel in which the light-emitting element 100 that emits light of a red wavelength is disposed, a green sub-pixel in which the light-emitting element 100 that emits light of a green wavelength is disposed, and a blue sub-pixel in which the light-emitting element 100 that emits light of a blue wavelength is disposed. The plurality of sub-pixels may further include a white sub-pixel.

Referring to FIGS. 2 and 3, the plurality of pixels PXL may be successively arranged in the first direction (the X-axis direction) and the second direction (the Y-axis direction). The plurality of sub-pixels of the same color may be disposed within the pixel of the display area 12. For example, each of the plurality of sub-pixels may include a first red sub-pixel in which a first-first red light-emitting element 100R that emits light of a red wavelength is disposed, a second red sub-pixel in which a first-second red light-emitting element 100R′ that emits light of a red wavelength is disposed, a first green sub-pixel in which a second-first green light-emitting element 100G that emits light of a green wavelength is disposed, a second green sub-pixel in which a second-second green light-emitting element 100G′ that emits light of a green wavelength is disposed, a first blue sub-pixel in which a third-first blue light-emitting element 100B that emits light of a blue wavelength is disposed, and a second blue sub-pixel in which a third-second blue light-emitting element 100B′ that emits light of a blue wavelength is disposed. The first-first red light-emitting element 100R, the second-first green light-emitting element 100G, and the third-first blue light-emitting element 100B may be regarded as main light-emitting elements.

The first-second red light-emitting element 100R′, the second-second green light-emitting element 100G′, and the third-second blue light-emitting element 100B′ may be regarded as sub-light-emitting elements.

One sub-pixel may include at least one or more light-emitting elements, and in the event that one light-emitting element becomes defective, the luminance of another light-emitting element may be increased to adjust the luminance of the sub-pixel. However, the embodiment is not necessarily limited thereto, and one sub-pixel may include only one light-emitting element.

A plurality of first electrodes 102 may each be disposed below the light-emitting element 100, and may be selectively connected to a plurality of signal wires TL1 to TL6 by an extension portion 102a. The high potential voltage may be applied to the pixel driving circuit through the signal wires TL1 to TL6. The signal wires TL1 to TL6 and the first electrodes 102 may be formed as integrated electrode patterns during the electrode patterning process.

For example, a first signal wire TL1 may be connected to an anode electrode of the first red sub-pixel, and a second signal wire TL2 may be connected to an anode electrode of the second red sub-pixel. A third signal wire TL3 may be connected to an anode electrode of the first green sub-pixel, and a fourth signal wire TL4 may be connected to an anode electrode of the second green sub-pixel. A fifth signal wire TL5 may be connected to an anode electrode of the first blue sub-pixel, and a sixth signal wire TL6 may be connected to an anode electrode of the second blue sub-pixel. When one sub-pixel includes only one light-emitting element, the number of the signal wires TL may be reduced by half.

A second electrode 104 may be a cathode electrode that is disposed one for each row and applies a cathode voltage to the light-emitting elements 100 arranged successively in the first direction (the X-axis direction). A plurality of second electrodes 104 may be spaced apart from each other in the second direction (the Y-axis direction). The plurality of second electrodes 104 may be connected to the cathode voltage through a contact electrode 106. Each of the plurality of second electrodes 104 may be electrically connected to the contact electrode 106. However, the embodiment is not necessarily limited thereto, and the second electrode 104 may be configured as one electrode layer without being divided into a plurality of electrodes and may function as a common electrode.

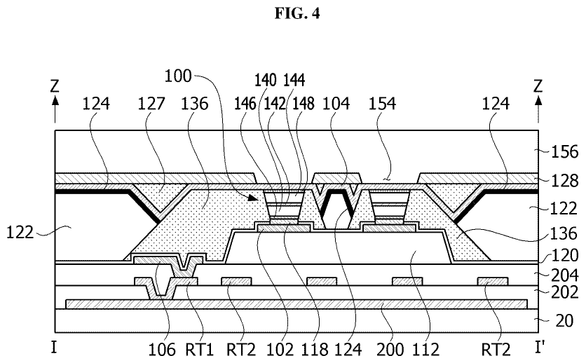

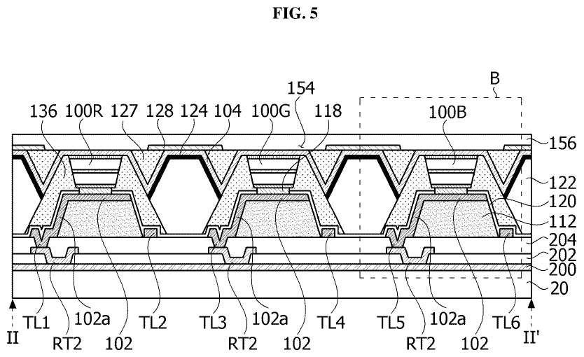

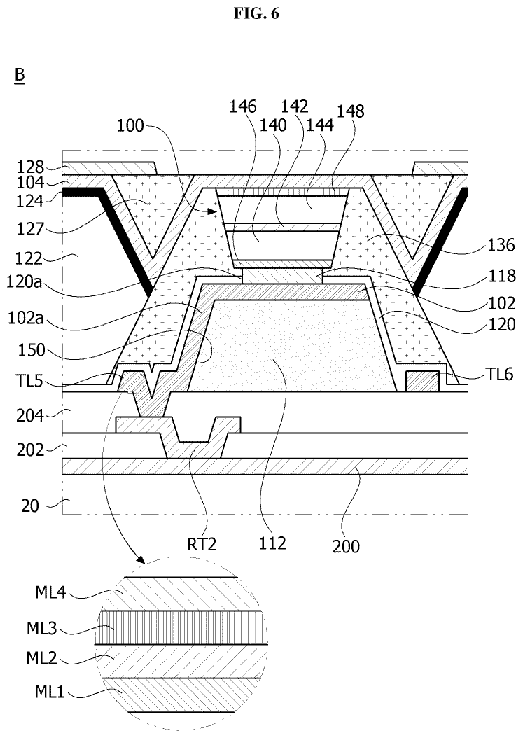

FIG. 4 is a cross-sectional view taken along line I-I′ in FIG. 3 according to one embodiment of the present disclosure. FIG. 5 is a cross-sectional view taken along line II-II′ in FIG. 3 according to one embodiment of the present disclosure. FIG. 6 is an enlarged view of an area ‘B’ in FIG. 5 according to one embodiment of the present disclosure.

Referring now to FIGS. 4 to 6, the display device according to embodiments of the present disclosure may include at least one of a substrate 20, a plurality of first electrodes 102 and contact electrodes 106 disposed on the substrate 20, a plurality of light-emitting elements 100 disposed on the plurality of first electrodes 102, a first optical layers 136 disposed between the plurality of light-emitting elements 100, a first components 122 disposed between the plurality of light-emitting elements 100, and a metal layer 124 surrounding the first components 122. In an embodiment, the first component 122 may be referred to as different other terms. For example, the first component 122 may be referred to as a mirror bank, a reflection bank, a mirror unit, an optical control unit, or an optical control element. However, the embodiment is not limited to these terms.

The substrate 20 may be made of plastic having flexibility. For example, the substrate 20 may be fabricated as a single-layer or multi-layer substrate of a material selected from, but not limited to, polyimide, polyethylene terephthalate, polyethylene naphthalate, polycarbonate, polyethersulfone, polyarylate, polysulfone, and cyclic olefin copolymer. For example, the substrate 20 may be a ceramic substrate or a glass substrate.

A pixel driving circuit 200 may be disposed in the display area 12 on the substrate 20. The pixel driving circuit 200 may include a plurality of thin film transistors using an amorphous silicon semiconductor, a polycrystalline silicon semiconductor, or an oxide semiconductor.

The pixel driving circuit 200 may include at least one driving thin film transistor, at least one switching thin film transistor, and at least one storage capacitor. When the pixel driving circuit 200 includes a plurality of thin film transistors, the plurality of thin film transistors may be formed on the substrate 20 by a thin film transistor (TFT) manufacturing process. Depending on embodiments, the pixel driving circuit 200 may be a collective term for the plurality of thin film transistors electrically connected to the light-emitting element 100.

The pixel driving circuit 200 may be a driver manufactured using a metal-oxide-silicon field effect transistor (MOSFET) manufacturing process on a single crystal semiconductor substrate 20. The driver may include a plurality of pixel driving circuits to drive the plurality of sub-pixels. When the pixel driving circuit 200 is implemented as the driver, an adhesive layer may be disposed on the substrate 20 and then the driver may be mounted on the adhesive layer by a transfer process.

A buffer layer 202 covering the pixel driving circuit 200 may be disposed on the substrate 20. The buffer layer 202 may be made of an organic insulating material, e.g., photosensitive photo acryl or photosensitive polyimide, but is not limited thereto.

An insulating layer 204 may be disposed on the buffer layer 202. The insulating layer 204 may be made of an organic insulating material, e.g., photosensitive photo acryl or photosensitive polyimide, but is not limited thereto.

Connection wires RT1 and RT2 may be disposed on the buffer layer 202. The connection wires RT1 and RT2 may be connected as the corresponding signal wires TL1 to TL6 or may be connected to the signal wires TL1 to TL6. The connection wires RT1 and RT2 may include a plurality of wire patterns disposed in different layers with one or more insulating layers interposed therebetween. The wire patterns disposed in different layers may be electrically connected through a contact hole penetrating the insulating layers.

At least a portion of the first connection wire RT1 may be disposed on the buffer layer 202 and at least another portion of the first connection wire RT1 may be connected to the pixel driving circuit 200 by penetrating through the buffer layer 202.

At least one of the contact electrodes 106, a plurality of bank patterns 112, and a passivation layer 120 may be disposed on the insulating layer 204.

At least a portion of the contact electrode 106 may be disposed on the insulating layer 204, and at least another portion of the contact electrode 106 may be electrically connected to the first connection wire RT1 by penetrating the insulating layer 204.

The contact electrode 106 and the signal wires TL1 to TL6 may be disposed on the same plane. At least a portion of the signal wires TL1 to TL6 may be disposed on the insulating layer 204, and at least another portion of the signal wires TL1 to TL6 may be electrically connected to the second connecting wire RT2 by penetrating the insulating layer 204.

The bank pattern 112 may be formed of an organic insulating material, such as, but not limited to, a photosensitive photo acryl or photosensitive polyimide. The bank pattern 112 may guide a position to which the light-emitting element 100 is to be attached during the transfer process of the light-emitting element 100. Depending on embodiments, the bank pattern 112 may be omitted.

A solder pattern 118 may be disposed on the first electrode 102. The solder pattern 118 may be made of indium (In), tin (Sn), or an alloy thereof, but is not limited thereto.

The passivation layer 120 may be formed to cover the insulating layer 204, the contact electrode 106, the bank pattern 112, and at least a portion of the first electrode 102. The passivation layer 120 may expose the first electrode 102. The light-emitting element 100 and the first electrode 102 may be connected through the portion exposed by the passivation layer 120.

At least one light-emitting element 100 may be disposed on the bank pattern 112. In an embodiment, the first electrode 102 may be disposed on the bank pattern 112. A solder pattern 118 may be disposed on the first electrode 102. The light-emitting element 100 may be mounted on the solder pattern 118. At least one light-emitting element 100 may be disposed on the solder pattern 118.

In an embodiment, one pixel may include light-emitting elements 100 of three colors 100. For example, the light-emitting elements 100 may include a red light-emitting element, a green light-emitting element, or a blue light-emitting element. One pixel may include a plurality of sub-pixels, and each of the plurality of sub-pixels may include a different color of light-emitting element 100. Depending on embodiments, two light-emitting elements may be mounted on each of the plurality of sub-pixels. In this case, one light-emitting element may be a first-first light-emitting element for normally emitting light (e.g., a first-first red light-emitting element 100R in FIG. 3), and the other light-emitting element may be a first-second light-emitting element disposed in readiness for a case where the first light-emitting element becomes defective (e.g., a first-second red light-emitting element 100R′ in FIG. 3).

In an embodiment, the light-emitting elements 100 shown in FIG. 4 may be light-emitting elements that emit the same color. The light-emitting elements 100 shown in FIG. 5 may be light-emitting elements that emit different colors.

The first component 122 may be disposed between the plurality of light-emitting elements 100. For example, as shown in FIG. 5, the first component 122 may be disposed between the first-first red light-emitting element 100R and a second-first green light-emitting element 100G.

The first component 122 may include an organic film. For example, the first component 122 may be formed of an organic film including an organic material. The organic material may include, for example, but is not limited to, acrylic, siloxane, poly(methyl methacrylate) (PMMA), benzocyclobutene (BCB), polyimide, epoxy, and polyester.

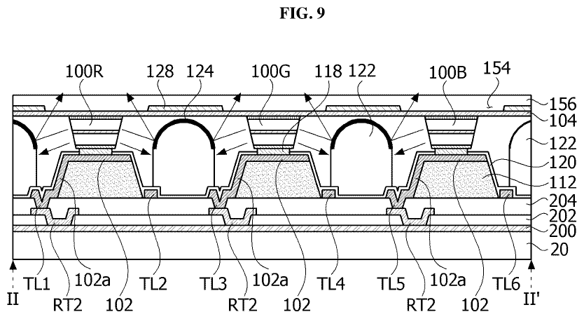

In an embodiment, the upper surface of the first component 122 may be formed equal to or higher than the height of the upper surface of the light-emitting element 100. The upper surface of the first component 122 may be formed flat or co-planar with the upper surface of the light-emitting element 100. The sides of the first component 122 may be formed to be sloped or to have a constant angle. The sides of the first component 122 may have a tapered shape. In another embodiment, the first component 122 may be formed in a variety of shapes, such as a lens shape. A more specific example of the above is shown in FIG. 9.

The metal layer 124 may be formed to surround the upper surface and the sides of the first component 122. The metal layer 124 may be formed of, for example, but not limited to, titanium (Ti) or aluminum (Al), which are metals having high light reflectivity. The metal layer 124 may reflect light emitted from the sides of the light-emitting element 100, thereby increasing light extraction efficiency. For example, when the light-emitting element 100 emits light, at least a portion of the emitted light may be incident toward the metal layer 124, which may reflect this incident light, thereby increasing the light extraction efficiency.

The first optical layer 136 may cover the plurality of light-emitting elements 100 and the plurality of bank patterns 112. Accordingly, the first optical layer 136 may cover between the plurality of light-emitting elements 100 and between the plurality of bank patterns 112. The first optical layer 136 may extend in the first direction X, and may be spaced apart in the second direction Y and separated between the pixel rows.

The first optical layer 136 may include an organic insulating material in which fine metal particles such as titanium dioxide particles are dispersed. Light emitted from the plurality of light-emitting elements 100 may be scattered by the fine metal particles dispersed in the first optical layer 136 and emitted to the outside.

The second electrode 104 may be disposed on the plurality of light-emitting elements 100. The second electrode 104 may be commonly connected to the plurality of pixels PXL. The second electrode 104 may be a thin electrode through which light is transmitted. The second electrode 104 may be made of a transparent electrode material, e.g., indium tin oxide (ITO), but is not necessarily limited thereto.

The second electrode 104 may extend on the plurality of light-emitting elements 100 and cover a portion of the first optical layer 136 and the metal layer 124.

The second electrode 104 may extend in the first direction (the X-axis direction) and may be spaced apart in the second direction (the Y-axis direction). On a plane, each of the plurality of second electrodes 104 may overlap the first optical layer 136 and may cover a plane outside of the first optical layer 136.

A second optical layer 127 may be an organic insulating material disposed on the upper portion of the second electrode 104. The second optical layer 127 may include the same material as the first optical layer 136, (e.g., siloxane). However, the embodiment is not necessarily limited thereto, and the first optical layer 136 and the second optical layer 127 may be formed of the same material or different materials.

The second optical layer 127 may be disposed to cover an upper portion of at least a portion of the second electrode 104. The second optical layer 127 may cover between the light-emitting element 100 and the first component 122. That is, the first optical layer 136 and the second optical layer 127 may function as a planarization layer. As a result, a pattern of a black matrix 128 on the second electrode 104 and the second optical layer 127 may be easily formed because there is no step in the plane on which the black matrix 128 is formed. However, the embodiment is not necessarily limited thereto, and the top surfaces of the second optical layer 127 and the second electrode 104 may have different heights.

The black matrix 128 may be an organic insulating material to which a black pigment is added. The second electrode 104 may be in contact with the contact electrode 106 below the black matrix 128. A transmission hole 154 may be formed between the patterns of the black matrix 128, through which light emitted from the light-emitting element 100 exits to the outside. The problem of mixing of light emitted from adjacent light-emitting elements 100 due to the first optical layer 136 may be improved by the black matrix 128.

A cover layer 156 may be an organic insulating material that covers the black matrix 128 and the second electrode 104. In FIGS. 6 to 10, the configuration of the cover layer 156 is omitted.

Referring to FIG. 6, the extension portion 102a of the first electrode 102 may extend to one side 150 of the bank pattern 112 and be disposed on the insulating layer 204, and may be electrically connected to the connection wire RT2.

In an embodiment, at least one of the first electrode 102, the extension portion 102a, the signal wire TL, and/or the connection wires RT1 and RT2 may include a single-layer or a multi-layer metal selected from titanium (Ti), molybdenum (Mo), and aluminum (Al). The first electrode 102, the extension portion 102a, the signal wire TL, and/or the connection wire RT1 and RT2 may be formed in a multi-layer structure including a first layer ML1, a second layer ML2, a third layer ML3, and a fourth layer ML4.

For example, the first layer ML1 and the third layer ML3 may include titanium (Ti) or molybdenum (Mo). The second layer ML2 may include aluminum (Al). The fourth layer ML4 may include a transparent conductive oxide layer, such as indium tin oxide (ITO) or indium zinc oxide (IZO), which has good adhesion to the solder pattern 118, corrosion resistance, and acid resistance.

The first layer ML1, the second layer ML2, the third layer ML3, and the fourth layer ML4 may be deposited sequentially and then patterned by performing a photolithography process and an etching process.

The passivation layer 120 may include an opening hole 120a disposed on the first electrode 102 and the signal wire TL and exposing the solder pattern 118.

The light-emitting element 10 may include a first conductivity type semiconductor layer 140, an active layer 142 disposed on the first conductivity type semiconductor layer 140, and a second conductivity type semiconductor layer 144 disposed on the active layer 142. A first driving electrode 146 may be disposed on the lower portion of the first conductivity type semiconductor layer 140 and a second driving electrode 148 may be disposed on the upper portion of the second conductivity type semiconductor layer 144.

The light-emitting element 100 may be formed on a silicon wafer by using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductivity type semiconductor layer 140 may be implemented with a compound semiconductor such as a group III-V or a group II-VI and may be doped with a first dopant. The first conductive type semiconductor layer 140 may be formed of one or more of the semiconductor materials having an empirical formula of Alₓ₁In_{y1}Ga_{(1-x1-y1)}N (0≤x1≤1, 0≤y1≤1, 0≤x1+y1≤1), InAlGaN, AlGaAs, GaP, GaAs, GaAsP, and AlGaInP, but is not limited thereto. When the first dopant is an n-type dopant such as Si, Ge, Sn, Se, or Te, the first conductivity type semiconductor layer 140 may be an n-type nitride semiconductor layer. However, when the first dopant is a p-type dopant, the first conductivity type semiconductor layer 140 may be a p-type nitride semiconductor layer.

The active layer 142 is a layer where electrons (or holes) injected through the first conductivity type semiconductor layer 140 and holes (or electrons) injected through the second conductivity type semiconductor layer 144 meet. The active layer 142 may transition to a low energy level as the electrons and the holes recombine, and may generate light having a corresponding wavelength.

The active layer 142 may have any one of a single well structure, a multi-well structure, a single quantum well structure, a multi-quantum well (MQW) structure, a quantum dot structure, or a quantum wire structure, but the structure of the active layer 142 is not limited thereto.

The active layer 142 may generate light in a visible wavelength band. For example, the active layer 142 may output light in any one of blue, green, and red wavelength bands.

The second conductivity type semiconductor layer 144 may be disposed on the active layer 142. The second conductivity type semiconductor layer 144 may be implemented with a compound semiconductor such as a group III-V or a group II-VI, and the second conductivity type semiconductor layer 144 may be doped with a second dopant. The second conductive semiconductor layer 144 may be formed of a material selected from a semiconductor material having an empirical formula of Inₓ₂Al_{y2}Ga_{1-x2-y2}N (0≤x2≤1, 0≤y2≤1, 0≤x2+y2≤1) or AlInN, AlGaAs, GaP, GaAs, GaAsP, and AlGaInP. When the second dopant is a p-type dopant such as Mg, Zn, Ca, Sr, or Ba, the second conductivity type semiconductor layer 144 doped with the second dopant may be a p-type nitride semiconductor layer. When the second dopant is an n-type dopant, the second conductivity type semiconductor layer 144 may be an n-type nitride semiconductor layer.

Although the light-emitting element has been described as having a vertical structure with driving electrodes 146 and 148 disposed at the upper and lower portions of the light-emitting structure in the embodiments, the light-emitting element may also have a lateral structure or a flip chip structure in addition to the vertical structure.

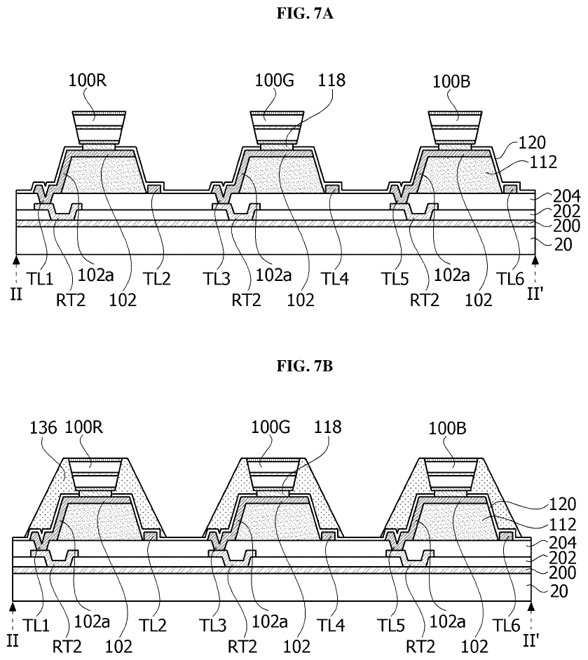

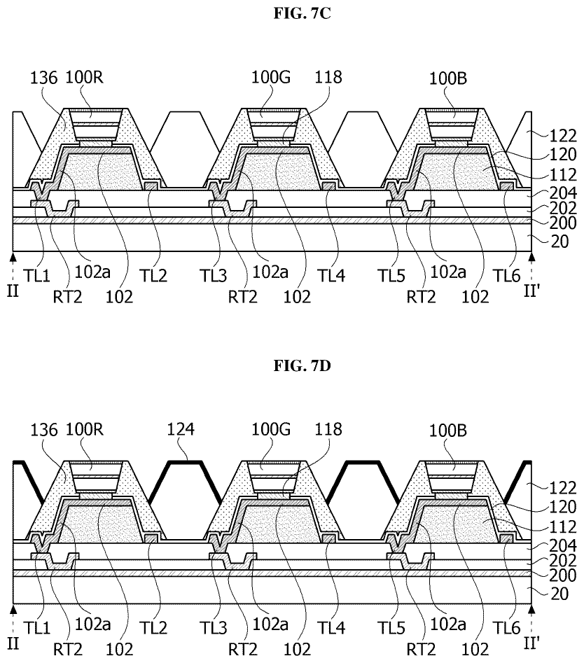

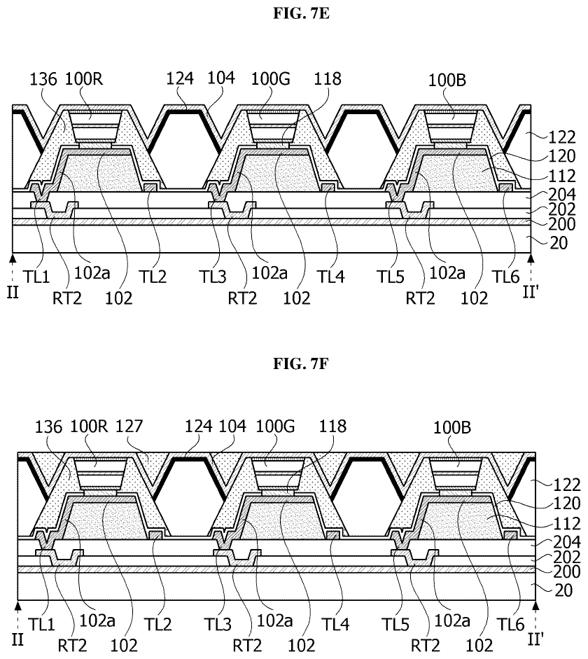

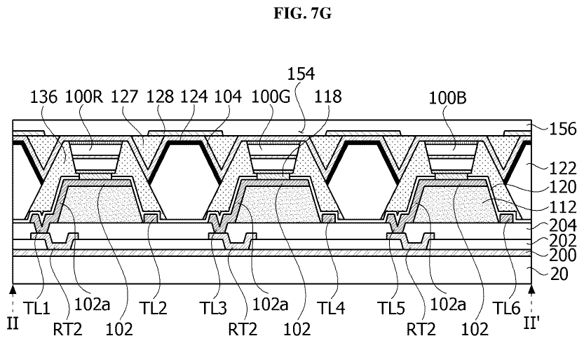

FIGS. 7A to 7G are schematic cross-sectional views to illustrate a manufacturing process for a display device according to one embodiment. Hereinafter, the manufacturing process of the display device will be described with reference to FIGS. 7A to 7G, but redundant descriptions of each component will be omitted.

Referring to FIG. 7A, the pixel driving circuit 200 may be formed on the substrate 20, and the buffer layer 202 may be formed thereon. The pixel driving circuit 200 may receive a driving voltage, an image signal (digital signal), a synchronization signal synchronized with the image signal, and the like, and may output an anode voltage and a cathode voltage of the light-emitting element 100 to drive the plurality of pixels. The pixel driving circuit 200 may be disposed in the non-display area 14, or may be disposed below the display area 12.

The connection wires RT1 and RT2 may then be formed on the buffer layer 202, followed by the insulating layer 204. The connection wires RT1 and RT2 may be electrically connected to the pixel driving circuit 200 by penetrating the buffer layer 202. The number of connection wires RT1 and RT2 and the number of times the connection wires are stacked in order to drive each pixel may be varied in various ways. For example, the number of times the connecting wires RT1 and RT2 and the insulating layer 204 are stacked may be two or more.

The plurality of bank patterns 112 may be disposed on the insulating layer 204. A bank pattern 112 may guide a position to which the light-emitting element 100 is to be attached during the transfer process of the light-emitting element 100. Accordingly, a position at which the light-emitting element 100 is transferred may be selected based on the bank pattern 112. The bank pattern 112 may be formed of an organic insulating material, such as, but not limited to, a photosensitive photo acryl or photosensitive polyimide. Depending on embodiments, the bank pattern 112 may be omitted.

An electrode material may be applied on the insulating layer 204 and the bank pattern 112. The applied electrode material may be patterned to form a plurality of first electrodes 102 and the contact electrode 106. The plurality of first electrodes 102 are areas where the light-emitting elements 100 are disposed, and the contact electrode 106 is an area where the second electrode 104 is electrically connected. Thereafter, the passivation layer 120 may be formed on the remaining electrode areas except for the areas where the plurality of first electrodes 102 and the contact electrode 106 are formed.

The solder patterns 118 may be formed on the first electrodes 102. The solder patterns 118 may be made of indium (In), tin (Sn), or an alloy thereof, but is not limited thereto.

On each of the solder patterns 118, the light emitting elements 100 (e.g., the red light-emitting element 100R, the green light-emitting element 100G, and the blue light-emitting element 100B) may be transferred. For example, as shown, one light-emitting element 100 may be transferred onto one solder pattern 118. One pixel may include the light-emitting elements 100 of three colors. The first light-emitting element may be the red light-emitting elements 110R and 110R′, the second light-emitting element may be the green light-emitting elements 110G and 110G′, and the third light-emitting element may be the blue light-emitting elements 110B and 110B′. Two light emitting elements may be mounted on each sub-pixel, but are not limited thereto.

A transfer method of the light-emitting element 100 is not particularly limited, and various transfer methods may be used. For example, the light-emitting element 100 grown on a semiconductor growth substrate may first be transferred to the transfer substrate and then secondly transferred to the substrate 20. In another example, the light-emitting element 100 grown on a semiconductor growth substrate may be transferred directly to the substrate 20.

Referring to FIG. 7B, after the light-emitting element 100 is transferred, the first optical layer 136 may be formed to cover the sides of the plurality of light-emitting elements 100 and the bank patterns 112. In this case, the first optical layer 136 may cover between the plurality of light-emitting elements 100 and between the plurality of bank patterns 112. At this time, the upper surface of the light-emitting elements 100 may be exposed to the upper portion of the first optical layers 136.

The first optical layers 136 may include an organic material. Fine metal particles such as titanium dioxide particles may be dispersed in the organic insulating material of the first optical layers 136. In this case, light emitted from the light-emitting elements 100 may be scattered and exited by the fine metal particles dispersed in the first optical layers 136.

Referring to FIG. 7C, after the first optical layer 136 is formed, the first component 122 may be disposed between the plurality of light-emitting elements 100. The first component 122 may be disposed on the upper portion of the insulating layer 204 and the first electrode 102. The first component 122 may be formed of an organic film. The upper surface of the first component 122 may be formed equal to or higher than the height of the upper surface of the light-emitting element 100. The sides of the first component 122 may be tapered. The first component 122 may be formed in a variety of shapes, including a lens shape.

Referring to FIG. 7D, the metal layer 124 may be disposed on the first component 122. The metal layer 124 may be formed to surround the upper surface and the sides of the first component 122. The metal layer 124 may be formed of, for example, but not limited to, titanium (Ti) or aluminum (Al) having high light reflectivity. The metal layer 124 may reflect light emitted from the sides of the light-emitting element 100, thereby increasing light extraction efficiency. The metal layer 124 may be referred to as a reflective layer or a light reflective layer depending on the embodiments, but is not limited to these terms.

Referring to FIG. 7E, the second electrode 104 may be disposed on the metal layer 124, the light-emitting element 100, and the first optical layer 136. The second electrode 104 may be disposed to cover the metal layer 124, the light-emitting element 100, and the first optical layer 136.

Referring to FIG. 7F, the second optical layer 127 may be disposed on at least a portion of the second electrode 104. For example, the second optical layer 127 may be formed to cover the second electrode 104 disposed between the light-emitting element 100 and the first component 122. When the second optical layer 127 is disposed between the light-emitting element 100 and the first component 122, the upper surface of the second optical layer 127 may be disposed flat or co-planar with the upper surface of the second electrode 104 on the light-emitting element 100, as shown.

Referring to FIG. 7G, the black matrix 128 may be formed to cover portions of the second electrode 104 and the second optical layer 127. The black matrix 128 may be disposed between the plurality of light-emitting elements 100. The black matrix 128 may cover at least a portion of the upper surface of the second electrode 104. The black matrix 128 may include a black pigment. The black matrix 128 may block light. The problem of mixing of light emitted from adjacent light-emitting elements 100 due to the first optical layer 128 may be improved by blocking the light with the black matrix 128.

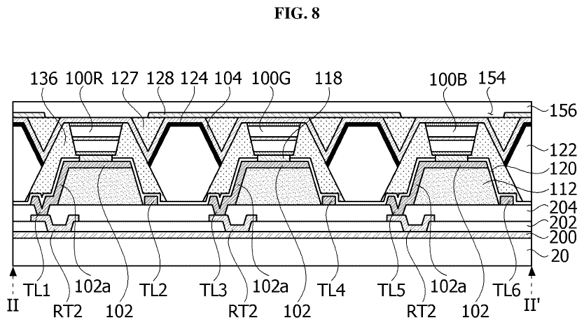

FIG. 8 is a cross-sectional view taken along line II-II′ in FIG. 3 according to another embodiment.

Referring to FIG. 8, the black matrix 128 may be disposed on the upper portion of the plurality of first components 122. For example, as shown, the black matrix 128 may be formed to cover the plurality of first components 122 and the green light-emitting element 100G. The black matrix 128 may be disposed on the upper portions of the second electrode 104 and the second optical layer 127. The black matrix 128 may be disposed on one light-emitting element 100 (e.g., green light-emitting element 100G), and thus may prevent or at least reduce color mixing between the light-emitting elements 100 that emit different colors.

FIG. 9 is a cross-sectional view taken along line II-II′ in FIG. 3 according to another embodiment.

Referring to FIG. 9, the metal layer 124 may be disposed in a circular shape on the upper portion of the first component 122. While the above modified embodiment is described in a structure in which the metal layer 124 is disposed in a circular shape, the shape of the metal layer 124 is not limited thereto.

The display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present specification may be applied to an organic light emitting lighting device or an inorganic light emitting lighting device.

The display device according to various embodiments of the present disclosure may be described as follows.

The display device according to the embodiment of the present disclosure may comprise a plurality of first electrodes and a contact electrode disposed on a substrate; a first bank and a second bank disposed on the substrate; a first light-emitting element disposed on the first bank; a second light-emitting element disposed on the second bank; a first optical layer and a first component disposed between the first light-emitting element and the second light-emitting element; and a second electrode disposed on the first light-emitting element and the second light-emitting element, wherein the second electrode extends outwardly of the first optical layer disposed between the first light-emitting element and the second light-emitting element and is electrically connected to the contact electrode.

According to one embodiment of the present disclosure, the display device may further comprise a second optical layer disposed on the upper portion of a portion of the second electrode.

According to one embodiment of the present disclosure, each of the first optical layer and the second optical layer may include light scattering particles.

According to one embodiment of the present disclosure, at least a portion of the upper surface of the first component may be equal to or higher than the upper surface of the light-emitting element.

According to one embodiment of the present disclosure, the display device may further comprise a metal layer surrounding at least a portion of the first component.

According to one embodiment of the present disclosure, a black matrix may be disposed on the upper portion of the metal layer.

According to one embodiment of the present disclosure, the display device may further comprise a plurality of signal wires extending between the first bank and the second bank and connected to the plurality of first electrodes.

According to one embodiment of the present disclosure, the contact electrode may be disposed between the plurality of signal wires.

According to one embodiment of the present disclosure, the second electrode may include a plurality of second electrodes spaced and disposed apart from each other for each pixel row of pixels, and each of the plurality of second electrodes is electrically connected to the contact electrode.

According to one embodiment of the present disclosure, at least some of the plurality of second electrodes may be disposed on the upper portions of the first light-emitting element and the second light-emitting element and a metal layer surrounding at least a portion of the first component and on the sides of the first optical layer.

According to one embodiment of the present disclosure, the display device may further comprise an insulating layer disposed on the substrate; a plurality of connection wires disposed between the substrate and the insulating layer; and a pixel driving circuit connected to the plurality of connection wires, wherein the plurality of connection wires is electrically connected to the plurality of first electrodes and the contact electrode.

According to one embodiment of the present disclosure, each of the first light-emitting element and the second light-emitting element may be connected by a different connection wire of the plurality of connection wires.

According to one embodiment of the present disclosure, each of the first light-emitting element and the second light-emitting element may include an inorganic light-emitting diode.

According to one embodiment of the present disclosure, the metal layer may reflect light emitted from the sides of the first light-emitting element and the second light-emitting element towards upper portions of the first light-emitting element and the second light-emitting element.

According to one embodiment of the present disclosure, the metal layer may be disposed in a circular shape.

The effects of the present specification are not limited to the above-mentioned effects, and other effects which are not mentioned will be clearly understood by those skilled in the art from the description in claims.

Although embodiments of the present disclosure have been described in more detail with reference to the accompanying drawings, the present disclosure is not necessarily limited to the embodiments, and various modifications may be carried out without departing from the technical spirit of the present disclosure. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A display device comprising:
a plurality of first electrodes and a contact electrode on a substrate;
a first bank and a second bank on the substrate;
a first light-emitting element on the first bank;
a second light-emitting element on the second bank;
a first optical layer and a first component between the first light-emitting element and the second light-emitting element; and
a second electrode on the first light-emitting element and the second light-emitting element,
wherein the second electrode extends outwardly of the first optical layer disposed between the first light-emitting element and the second light-emitting element and is electrically connected to the contact electrode.

2. The display device of claim 1, further comprising:
a second optical layer on an upper portion of a portion of the second electrode.

3. The display device of claim 2, wherein each of the first optical layer and the second optical layer includes light scattering particles.

4. The display device of claim 1, wherein at least a portion of an upper surface of the first component is equal to or higher than an upper surface of the light-emitting element.

5. The display device of claim 1, further comprising:
a metal layer surrounding at least a portion of the first component.

6. The display device of claim 5, wherein a black matrix is on an upper portion of the metal layer.

7. The display device of claim 1, further comprising:
a plurality of signal wires extending between the first bank and the second bank, the plurality of signal wires connected to the plurality of first electrodes.

8. The display device of claim 7, wherein the contact electrode is between the plurality of signal wires.

9. The display device of claim 5, wherein the second electrode includes a plurality of second electrodes spaced apart from each other for each pixel row of pixels, and each of the plurality of second electrodes is electrically connected to the contact electrode.

10. The display device of claim 9, wherein at least some of the plurality of second electrodes are on upper portions of the first light-emitting element and the second light-emitting element and a metal layer surrounding at least a portion of the first component and on sides of the first optical layer.

11. The display device of claim 1, further comprising:
an insulating layer on the substrate;
a plurality of connection wires between the substrate and the insulating layer; and
a pixel driving circuit connected to the plurality of connection wires,
wherein the plurality of connection wires are electrically connected to the plurality of first electrodes and the contact electrode.

12. The display device of claim 11, wherein each of the first light-emitting element and the second light-emitting element is connected by a different connection wire of the plurality of connection wires.

13. The display device of claim 1, wherein each of the first light-emitting element and the second light-emitting element includes an inorganic light-emitting diode.

14. The display device of claim 5, wherein the metal layer reflects light emitted from the sides of the first light-emitting element and the second light-emitting element towards upper portions of the first light-emitting element and the second light-emitting element.

15. The display device of claim 5, wherein the metal layer is disposed in a circular shape.
